(19) United States
(12) Patent Application Publication
(10) Pub. No.: US 2024/0097017 A1
(43) Pub. Date: Mar. 21, 2024

(54) VERTICAL MULTICHANNEL GALLIUM NITRIDE TRANSISTOR

(71) Applicant: Robert Bosch GmbH, Stuttgart (DE)

(72) Inventors: Jens Baringhaus, Sindelfingen (DE); Christian Huber, Ludwigsburg (DE); Daniel Krebs, Aufhausen (DE)

(21) Appl. No.: 18/466,206

(22) Filed: Sep. 13, 2023

(30) Foreign Application Priority Data
Sep. 19, 2022 (DE) 10 2022 209 797.1

(51) Int. Cl. H01L 29/778; H01L 29/20; H01L 29/423; H01L 29/66

(52) U.S. Cl. CPC H01L 29/7786; H01L 29/2003; H01L 29/42316; H01L 29/66462

(57) ABSTRACT

A semiconductor component designed as a vertical HEMT. The semiconductor component includes a substrate made of gallium nitride (GaN), a drift layer arranged thereon, and a heteroepitaxial structure which is arranged thereabove, is laterally contacted by source electrodes and is suitable for providing a conductive channel by forming a two-dimensional electron gas.

### FIELD

The present invention relates to a semiconductor component on the basis of gallium nitride, in particular to a field-effect transistor designed as a vertical HEMT (high-electron-mobility transistor).

### BACKGROUND INFORMATION

For semiconductor components designed as transistors, gallium nitride is a preferred material system or substrate material since semiconductor components on the basis of gallium nitride (GaN) generally have a low electrical resistance in the forward direction or in a forward operating state (on-resistance) with simultaneously higher breakthrough voltages or breakthrough field strengths in the blocking state of the semiconductor component, than comparable components on the basis of silicon or silicon carbide. With respect to the design of semiconductor components, in addition to a traditional, substantially horizontal arrangement of the electrodes, a vertically stacked arrangement of at least two electrodes of a component is furthermore also a possible design alternative in order to be able to provide correspondingly miniaturized semiconductor components.

One conventional type of a field-effect transistor is the so-called HEMT (high-electron-mobility transistor), also called CAVET (current aperture vertical electron transistor), which comprises layers of different semiconductor materials with different band gaps, wherein a two-dimensional electron gas (2DEG) forms at the interface of these layers and serves as a conductive channel. Further increases in the current-carrying capacity, energy density and operating frequency are possible as a result of the 2DEG, instead of the conventional channel region as in MOSFETs, for example. In articular, HEMTs have low noise in the high frequency range and have a very high transit frequency, which is why they can be advantageously used as fast switching elements.

One conventional embodiment of a generic vertical HEMT on the basis of AlGaN/GaN as the material system comprises a GaN substrate, a drift layer, a p-doped GaN region which is arranged thereon and is provided in the area of a gate electrode by an n-conductive GaN region, and wherein above the p-doped GaN region are provided an undoped GaN region and an AlGaN region as a heterogeneous layer system for forming a two-dimensional electron gas (2DEG). The disadvantage of this conventional structure is in particular the high forward resistance of the HEMT.

From the related art, a so-called trigate approach, in which the lateral HEMT comprises a plurality of 2DEG channels which are arranged one above the other and are laterally contacted via a gate, is also described for lateral HEMTs.

### SUMMARY

A semiconductor component according to the present invention, designed as a vertical HEMT on the basis of gallium nitride, may have an advantage that a forward resistance of the conductive channel or of a channel region is significantly reduced in comparison to the vertical HEMT from the related art.

It is provided in a semiconductor component according to an example embodiment of the present invention, designed as a vertical HEMT, that the semiconductor component comprises a substrate made of gallium nitride (GaN), a drift layer arranged thereon, and a heteroepitaxial structure which is arranged thereabove, is laterally contacted by source electrodes, and is suitable for providing a conductive channel by forming a two-dimensional electron gas in the heteroepitaxial structure, wherein the heteroepitaxial structure has a plurality of layer sequences lying one above the other and is designed to provide a plurality of channels arranged one above the other and consisting of two-dimensional electron gas.

In the present case, a plurality is understood to be a number of at least two. Advantageously, the heteroepitaxial structure comprises at least three layer sequences, lying one above the other, for forming at least three channels consisting of two-dimensional electron gas (2DEG). According to the present invention, the plurality of provided 2DEGs provides a multi-channel heteroepitaxial structure, which in particular comprises several parallel 2DEGs. The multi-channel heteroepitaxial structure is advantageously contacted on both sides by opposite source electrodes of the semiconductor component.

According to an example embodiment of the present invention, a respective layer sequence of the heteroepitaxial structure preferably consists of a first layer and a second layer lying directly above it, the layers consisting of different semiconductor materials having different band gaps. An advantageous material system for providing the heteroepitaxial structure according to the present invention is an aluminum gallium nitride (AlGaN)/gallium nitride (GaN) material system. Preferably in this case, a first layer is formed by an undoped GaN region and the layer lying above it is formed by an AlGaN region. The heteroepitaxial structure may also comprise alternative materials, such as an aluminum indium nitride (AlInN)/gallium nitride (GaN) material system, or a material system comprising aluminum nitride (AlN) or scandium nitride (ScN). In a stacked arrangement of the layer sequences, the respective material layers are preferably arranged to alternate in the resulting heteroepitaxial structure.

According to an example embodiment of the present invention, the semiconductor component advantageously comprises a p-doped GaN region arranged on the drift layer. This GaN region is advantageously interrupted by an n-doped GaN region in the area of a gate electrode. The n-doped GaN region enables a vertical current flow in the switched-on state of the semiconductor component.

In a preferred embodiment of the present invention, above the heteroepitaxial structure, the semiconductor component has a p-doped GaN region which is contacted by a gate electrode and is designed at least in sections to deplete the underlying heteroepitaxial structure. The p-doped GaN region is advantageously arranged above the n-doped region formed between two p-doped GaN regions. In particular, a depletion of the underlying heteroepitaxial structure can take place in an area arranged above the n-doped GaN region.

In a preferred embodiment of the present invention, the heteroepitaxial structure is designed in such a way that at least some of the layers of the heteroepitaxial structure, in particular in an area below a gate electrode, and further advantageously in a vertical area between the gate electrode and the n-doped GaN region structured above the drift layer, are provided with n-doping. Further advantageously, all layers of the heteroepitaxial structure in the aforementioned region can also be provided with n-doping. This in particular improves a vertical current flow through the heteroepitaxial structure.

Advantageously, according to an example embodiment of the present invention, an intermediate p-doped GaN layer can also be arranged between two layer sequences of the heteroepitaxial structure arranged one above the other. Analogously to an advantageously provided p-doped GaN region below the gate electrode, this intermediate p-doped GaN layer can deplete layers lying above and below it, or the 2DEGs formed therein. A self-locking design of the semiconductor can, for example, be realized as a result.

In a further, preferred embodiment of the present invention, the heteroepitaxial structure is designed to be structured like fins. The heteroepitaxial structure can in particular be structured in the form of narrow fins. Advantageously, the fin-like heteroepitaxial structure can be completely enclosed laterally and above by a p-doped GaN region contacted with the gate electrode. The multi-channel heteroepitaxial structure, including the intermediate layers optionally arranged therein, can in this case be designed as described above. In particular, the semiconductor component may have a plurality of heteroepitaxial structures that are structured like fins and extend parallel to one another between two source electrodes.

The semiconductor component according to the present invention can be self-locking or self-conducting.

Further advantages, features and details of the present invention result from the following description of preferred example embodiments of the present invention and on the basis of the figures.

### BRIEF DESCRIPTION OF THE DRAWINGS

FIG. 1 shows a section through a layer structure of a vertical HEMT according to the prior art.

FIG. 2 shows a section through a layer structure of a preferred embodiment of the semiconductor component according to the present invention.

FIG. 3 shows a section through a layer structure of a further, preferred embodiment of the semiconductor component according to the present invention.

FIG. 4 shows a perspective side view and associated partial sectional view of a further, preferred embodiment of the semiconductor component according to the present invention.

### DETAILED DESCRIPTION OF EXAMPLE EMBODIMENTS

The same elements or elements having the same function are provided with the same reference signs in the figures.

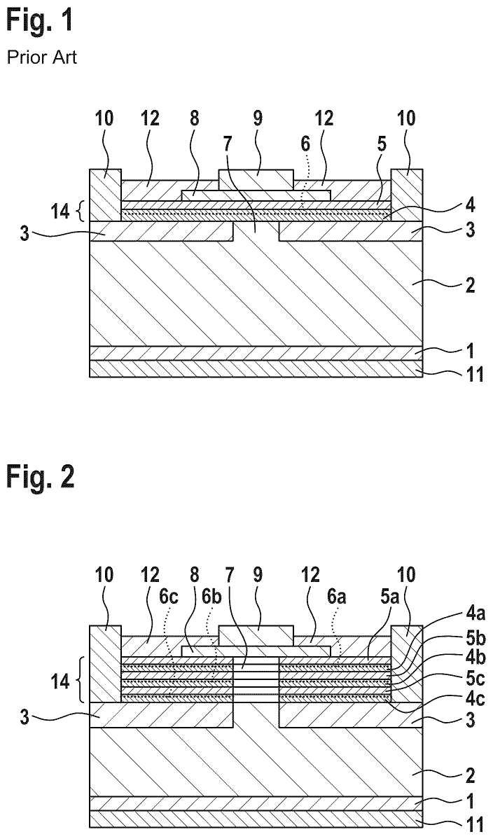

FIG. 1 shows the principal structure of a vertical HEMT according to the prior art.

The generic transistor 100 comprises a highly conductive n-doped GaN layer as substrate 1, onto which a weakly n-doped GaN drift zone 2 is applied. A p-doped GaN layer 3 is arranged on the drift zone 2 and is interrupted by an n-doped GaN region 7 in the area below a gate electrode 9. This interruption of the p-doped GaN layer 3 below the GaN region 4, in which a two-dimensional electron gas forms as a conductive channel as described below, enables a vertical current flow in the switched-on state of the transistor.

An undoped GaN region 4 as a first layer and an AlGaN region 5 as a second layer of a heteroepitaxial structure 14 for forming a two-dimensional electron gas (2DEG) are arranged above the p-doped GaN region 3 and the n-doped GaN region 7 interrupting it. In this case, the two-dimensional electron gas for providing a conductive channel 6 within the undoped region 4 forms at the AlGaN/GaN interface due to crystal lattice stress and piezoelectric polarization.

A p-doped GaN region 8, which is electrically contacted by a gate electrode 9, is located above the heterogeneous layer arrangement 4, 5, in particular in a section above the n-doped region 7. The p-doped GaN region 8 can in this case enable a “normally off” operation and thus the self-locking property of the field-effect transistor.

An insulation layer 12 is located above the AlGaN region 5. Source electrodes 10 for electrically contacting the 2DEG 6 are arranged laterally of the undoped GaN region 4 and the AlGaN region 5. A drain electrode 11 is assigned to the highly conductive n-doped GaN layer 1 on the rear side of the component.

Since the 2DEG 6 below the p-doped GaN region 8 is depleted, the transistor is self-locking without applying a gate voltage. By applying a positive voltage to the gate electrode 9, the 2DEG 6 is filled with electrons, thereby conductive, so that electrons flow from the source 10 flow through the 2DEG 6 into the n-doped GaN region 7, into the drift zone 2, and via the n-doped layer 1 into the drain electrode 11 when a drain voltage is applied.

FIG. 2 shows a preferred embodiment of the multi-channel GaN transistor according to the present invention. In this case, the structure substantially corresponds to the generic vertical HEMT according to FIG. 1. In deviation therefrom, the layer structure is now designed in such a way that, instead of a single 2DEG 6, a plurality of, i.e., at least two, and in particular three, 2DEGs 6a, 6b, 6c are provided as a channel for the current flow.

For this purpose, the semiconductor component according to the present invention comprises a heteroepitaxial structure 14 with a plurality of layer sequences 4a, 5a, 4b, 5b, 4c, 5c, which lie one above the other and are designed to provide a plurality of channels which are arranged one above the other and consist of two-dimensional electron gas 6a, 6b, 6c.

In deviation from the prior art, several layer sequences or heteroepitaxial layers each consisting of two different semiconductor materials with different band gaps are thus arranged vertically one above the other.

In a preferred embodiment, AlGaN/GaN is selected as the material system for the heteroepitaxial structure 14. Accordingly, the proposed arrangement comprises a layer stack consisting of the following layers: AlGaN 5a, GaN 4a, AlGaN 5b, GaN 4b, AlGaN 5c, and GaN 4c. The layer GaN 4c is arranged above the p-doped GaN layer 3.

Preferably, in a region 7 below the gate electrode 9, the corresponding layers of the multi-channel heteroepitaxial structure 14 are provided with n-doping, whereby a vertical current flow is facilitated even in the case of several layers arranged one above the other. Preferably, all layers or only selected layers, for example only every second layer in the vertical direction, can be provided with n-doping in the region 7.

The embodiment shown preferably exhibits a “normally on” or a self-conducting behavior since the effect of the gate potential as well as of the provided p-doped GaN layer 8 has a lesser effect on lower 2DEGs, for example the 2DEGs 6b, 6c.

In deviation from the described preferred embodiment, an alternative material system for forming the 2DEGs may be provided. For example, a material system comprising AlN, ScN, or an AlInN/GaN material system, which is suitable for forming a 2DEG serving as a conductive channel, may alternatively be provided.

Furthermore, in deviation from the embodiment shown, a deviating number, in particular also more than the shown three heteroepitaxial layers or layer sequences (e.g., 5a/4a) arranged one above the other, can also be provided for providing the multi-channel heteroepitaxial structure 14.

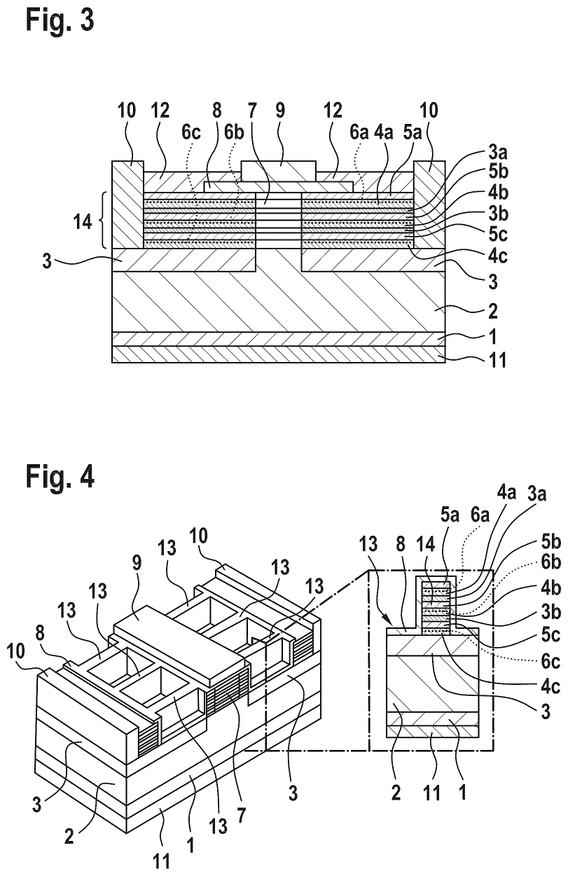

FIG. 3 shows a further, preferred embodiment of the semiconductor component according to the present invention. This embodiment substantially comprises a similar layer arrangement to the embodiment according to FIG. 2. In deviation therefrom, an additionally p-doped conductive layer 3a, 3b is provided after each layer sequence (e.g., 5a/4a). These additional p-doped layers serve to deplete the layers arranged vertically adjacent thereto, i.e., the respective layers above and below them, analogously to the p-doped GaN region 8 below the gate electrode 9. As a result, the semiconductor component 100 according to this embodiment can be designed to be self-locking (“normally off”).

FIG. 4 shows a further, preferred embodiment of the semiconductor component according to the present invention, wherein the insulation layer 12 is not shown for a better overview.

According to this embodiment, the layer structure of the epitaxial stack or the heteroepitaxial structure 14 comprises one or more fins 13 which are structured therein and in particular narrow and serve to form a respective channel area. This can, in particular, further increase the effect of the gate potential and a depletion of the 2DEGs 6a, 6b, 6c.

As shown in the partial sectional view of FIG. 4, the multi-channel heteroepitaxial structure 14 structured as fins and comprising the layers 4a-c, 5a-c, optionally 3a-b, as well as the resulting 2DEGs 6a-c is enclosed by the p-doped GaN region 8. In this case, if the fins are designed to be correspondingly narrower, as shown in FIG. 4, all 2DEGs 6a, 6b, 6c can be depleted by the p-doped region 8 enclosing them. As a result, the embodiment according to FIG. 4 can also be designed to be self-locking.

As shown in FIG. 4, the gate electrode 9 may be formed only in a central section above the region 7. Alternatively, the gate electrode 9 may be formed on a larger surface, e.g., the entire p-doped GaN region 8, in particular also between the fins.

In order to compensate for any higher resistance resulting due to the lateral delimitation of the fin-like multi-channel heteroepitaxial structure 14, the embodiment may have a correspondingly higher number of parallel channels. For example, the semiconductor component may comprise 4 to 10 parallel multi-channel heteroepitaxial structures 14.

1-10. (canceled)

11. A semiconductor component configured as a vertical high-electron mobility transistor (HEMT), comprising:
a substrate made of gallium nitride (GaN);
a drift layer arranged on the substrate; and
a heteroepitaxial structure arranged above the drift layer and laterally contacted by source electrodes and is configured to provide a conductive channel by forming a two-dimensional electron gas, wherein the heteroepitaxial structure includes a plurality of layer sequences lying one above the other and is configured to provide a plurality of channels which are arranged one above the other and include two-dimensional electron gas.

12. The semiconductor component according to claim 11, wherein in that each respective layer sequence of the heteroepitaxial structure includes a first layer and a second layer lying directly above the first layer, the first and second layers including different semiconductor materials with different band gaps.

13. The semiconductor component according to claim 11, wherein the heteroepitaxial structure includes an AlGaN/GaN material system.

14. The semiconductor component according to claim 11, wherein the semiconductor component further comprises, above the drift layer, a structured n-doped region between p-doped regions.

15. The semiconductor component according to claim 14, wherein the semiconductor component further comprises, above the heteroepitaxial structure, a p-doped GaN region which is contacted by a gate electrode and is configured to deplete the heteroepitaxial structure at least in an area located above the n-doped region.

16. The semiconductor component according to claim 11, wherein at least some layers of the heteroepitaxial structure in an area below a gate electrode are provided with n-doping.

17. The semiconductor component according to claim 11, wherein a p-doped layer is arranged between two of the layer sequences of the heteroepitaxial structure arranged one above the other.

18. The semiconductor component according to claim 11, wherein the heteroepitaxial structure is structured like fins and is completely enclosed laterally by a p-doped region contacted with a gate electrode.

19. The semiconductor component according to claim 18, wherein the semiconductor component has a plurality of heteroepitaxial structures that are structured like fins and extend parallel to one another between two source electrodes.

20. The semiconductor component according to claim 11, wherein the semiconductor component is self-locking or self-conducting.
